(19) United States
(12) Patent Application Publication
(10) Pub. No.: US 2018/0355472 A1
(43) Pub. Date: Dec. 13, 2018

(54) OXIDE-SINTERED-BODY SPUTTERING TARGET AND METHOD OF PRODUCING THE SAME

(71) Applicant: ULVAC, INC., Kanagawa (JP)

(72) Inventors: KAZUTOSHI TAKAHASHI, Kanagawa (JP); KOJI HIDAKA, Kanagawa (JP); YUU KAWAGOE, Kanagawa (JP); KENTAROU TAKESUE, Kanagawa (JP); MASARU WADA, Kanagawa (JP); MITSURU UENO, Kanagawa (JP); JUNYA KIYOTA, Kanagawa (JP); MOTOSHI KOBAYASHI, Kanagawa (JP); MASAKI TAKEI, Kanagawa (JP)

(73) Assignee: ULVAC, INC., Kanagawa (JP)

(21) Appl. No.: 15/778,086

(22) PCT Filed: Dec. 21, 2016
(86) PCT No.: PCT/JP2016/088182

§ 371 Date: May 22, 2018

(30) Foreign Application Priority Data
Dec. 25, 2015 (JP) 2015-252902

(51) Int. Cl. C23C 14/34; C04B 35/01; C04B 35/453; C04B 35/64; H01J 37/34; C23C 14/08

(52) U.S. Cl. CPC C23C 14/3414; C04B 35/01; C04B 35/453; C04B 35/64; H01J 37/3426; C04B 2235/3244; C23C 14/086; C04B 2235/3286; C04B 2235/3284; C04B 2235/3232; C23C 14/083

(57) ABSTRACT

An oxide-sintered-body sputtering target according to an embodiment of the present invention is formed of a sintered body containing an indium oxide, a zinc oxide, a titanium oxide, and a zirconium oxide, an atomic ratio of titanium with respect to a sum of indium, zinc, and titanium being not less than 0.1% and not more than 20%, a weight ratio of zirconium with respect to a sum of the indium oxide, the zinc oxide, the titanium oxide, and the zirconium oxide being not less than 10 ppm and not more than 2,000 ppm.

### TECHNICAL FIELD

The present invention relates to an oxide-sintered-body sputtering target used for depositing a metal oxide thin film, and a method of producing the same.

### BACKGROUND ART

In the past, metal oxides such as ITO (indium tin oxide), ZnO (zinc oxide), IZO (indium zinc oxide), and IGZO (indium gallium zinc oxide) have been used in various fields, e.g., fields of transparent electrode films of various displays, electronic parts, semiconductor devices, and the like.

For example, Patent Literature 1 discloses a thin-film transistor including a pixel electrode formed of a transparent conductive oxide such as ITO, IZO, and ZnO. Further, Patent Literature 2 discloses a method of producing a TFT array substrate including a metal oxide semiconductor film formed of IGZO, IZO, ZnO, or the like.

Patent Literature 1: Japanese Patent Application Laid-open No. 2013-25307

Patent Literature 2: Japanese Unexamined Patent Application Publication No. 2015-505168

### SUMMARY OF INVENTION

### Problem to be Solved by the Invention

This type of metal oxide thin film is typically deposited by a sputtering method using a target material formed of a sintered body of a metal oxide. However, the film quality of the metal oxide thin film is greatly affected by the quality of the sintered body constituting the sputtering target. For example, depending on the size of pinholes in the sintered body, nodules and abnormal discharge are likely to occur, which causes a problem that the number of particles is increased and the yield is reduced. For this reason, it has been necessary to increase the relative density of the sintered body by, for example, setting the firing temperature to a higher temperature, thereby suppressing the generation of particles as much as possible.

Meanwhile, although it is effective to increase the sintering temperature to improve the relative density of the sintered body, grain growth may excessively occur to reduce the mechanical strength of the sintered body, e.g., the sintered body is likely to break due to the reduction in flexural strength. Further, as precipitation of the oxide structure of a specific component cannot be suppressed, the specific resistance of the sintered body is increased, which may cause abnormal discharge at the time of the deposition.

In view of the circumstances as described above, it is an object of the present invention to provide an oxide-sintered-body sputtering target capable of suppressing the reduction in mechanical strength and the increase in specific resistance, and a method of producing the same.

### Means for Solving the Problem

In order to achieve the above-mentioned object, an oxide-sintered-body sputtering target according to an embodiment of the present invention is formed of a sintered body containing an indium oxide, a zinc oxide, a titanium oxide, and a zirconium oxide, an atomic ratio of titanium with respect to a sum of indium, zinc, and titanium being not less than 0.1% and not more than 20%, a weight ratio of zirconium with respect to a sum of the indium oxide, the zinc oxide, the titanium oxide, and the zirconium oxide being not less than 10 ppm and not more than 2,000 ppm.

The titanium oxide plays a role of an aid for improving the sinterability. Therefore, by setting the atomic ratio of titanium with respect to a sum of indium, zinc, and titanium to not less than 0.1% and not more than 20%, it is possible to suppress the specific resistance of the sintered body to be low to ensure stable DC sputtering while improving the relative density of the sintered body containing an indium oxide, a zinc oxide, a titanium oxide, and a zirconium oxide. Meanwhile, by setting the weight ratio of zirconium with respect to a sum of an indium oxide, a zinc oxide, a titanium oxide, and a zirconium oxide to not less than 10 ppm and not more than 2,000 ppm, it is possible to suppress the grain growth (grain coarsening) of the titanium oxide, and increase the flexural strength or bending strength of the sintered body, thereby suppressing occurrence of breaks or cracks.

As an embodiment, the weight ratio of zirconium with respect to the sum of the indium oxide, the zinc oxide, the titanium oxide, and the zirconium oxide is not less than 30 ppm and not more than 1,400 ppm, and an atomic ratio of zirconium with respect to titanium is not more than 0.6.

The sintered body typically has a relative density of not less than 95%.

Each of the oxides constituting the sintered body may have an average crystalline grain size of not more than 15 μm and a specific resistance of not less than 0.1 mΩ·cm and not more than 300 mΩ·cm.

The sintered body may include an alloy phase or a compound phase of an In₂O₃ phase and at least one of an In—Ti—O phase, a Zn—Ti—O phase, and an In—Zn—O phase.

The sintered body may include an In₂O₃ phase having an average particle size of not more than 15 μm.

A pinhole in the sintered body may have a circle equivalent diameter of not more than 1 μm.

A method of producing an oxide-sintered-body sputtering target according to an embodiment of the present invention includes:

preparing an indium oxide powder, a zinc oxide powder, a titanium oxide powder, and a zirconium oxide powder;

mixing the powders to prepare mixed powder in which an atomic ratio of titanium with respect to a sum of indium, zinc, and titanium is not less than 0.1% and not more than 20% and a weight ratio of zirconium with respect to a sum of an indium oxide, an zinc oxide, an titanium oxide, and an zirconium oxide is not less than 10 ppm and not more than 2,000 ppm; and

firing the mixed powder at a predetermined temperature.

As the titanium oxide powder, a raw material powder of a titanium oxide having a rutile ratio of not less than 80% and an average crystalline grain size of not more than 3 μm may be used.

The predetermined temperature may be not less than 1,240° C. and not more than 1,400° C.

### Advantageous Effects of Invention

As described above, according to the present invention, it is possible to provide an oxide-sintered-body sputtering target capable of suppressing the reduction in mechanical strength and the increase in specific resistance.

### BRIEF DESCRIPTION OF DRAWINGS

FIG. 1 A diagram showing a relationship between a Ti atomic ratio and a specific resistance, and a flexural strength and a relative density in an In—Zn—Ti—O sintered body according to an embodiment of the present invention.

FIG. 2 A a diagram showing a relationship between a Zr weight ratio and a specific resistance in the above-mentioned In—Zn—Ti—O sintered body.

FIG. 3 A diagram showing a relationship between a Zr weight ratio and a flexural strength in the above-mentioned In—Zn—Ti—O sintered body.

FIG. 4 A diagram showing a relationship between a Zr weight ratio and a relative density in the above-mentioned In—Zn—Ti—O sintered body.

FIG. 5 A diagram showing a Ti atomic ratio dependency of the firing temperature of the above-mentioned In—Zn—Ti—O sintered body having a relative density of 98.6% to 98.7%.

FIG. 6 An SEM image showing crystalline structures of In—Zn—Ti—O sintered bodies of three systems having different composition ratios.

FIG. 7 A process flow describing a method of producing an oxide-sintered-body sputtering target according to an embodiment of the present invention.

FIG. 8 An experimental result showing TMA of a sample powder obtained by adding two kinds of titanium oxide powders having different rutile ratios to powders of an indium oxide, a zinc oxide, and a zirconium oxide.

FIG. 9 A diagram showing a time change of TMA in FIG. 8.

### MODE(S) FOR CARRYING OUT THE INVENTION

Hereinafter, an embodiment of the present invention will be described with reference to the drawings.

### Sputtering Target

An oxide-sintered-body sputtering target according to an embodiment of the present invention (hereinafter, referred to also simply as sputtering target) is formed of a sintered body containing an indium oxide, a zinc oxide, a titanium oxide, and a small amount of a zirconium oxide (hereinafter, referred to also as In—Zn—Ti—O sintered body). The sputtering target is used as, for example, a target for deposition such as an active layer of a thin-film transistor, a transparent conductive film, a pixel electrode, and a transparent electrode of a solar power generation panel.

The sputtering target according to this embodiment has a configuration in which IZO (indium zinc oxide) is the main composition and predetermined amounts of Ti and Zr are added thereto.

In the above-mentioned sintered body (sputtering target), an atomic ratio of Ti (hereinafter, referred to also as Ti atomic ratio) with respect to a sum of In (indium), Zn (zinc), and Ti (titanium) is not less than 0.1% and not more than 20%. That is, the content of Ti relative to the total amount of In, Zn, and Ti that constitute the above-mentioned sintered body is not less than 0.1 at. % and not more than 20 at. %.

The titanium oxide plays a role of an aid for improving the sinterability. In the case where the Ti atomic ratio is less than 0.1%, the relative density of the sintered body containing an indium oxide, a zinc oxide, a titanium oxide, and a zirconium oxide is hard to be increased. Meanwhile, in the case where the Ti atomic ratio exceeds 20%, although the relative density of the above-mentioned sintered body is easily increased, precipitation of the titanium oxide alone is increased, and the specific resistance of the sintered body is extremely increased, which makes it difficult to ensure stable DC sputtering.

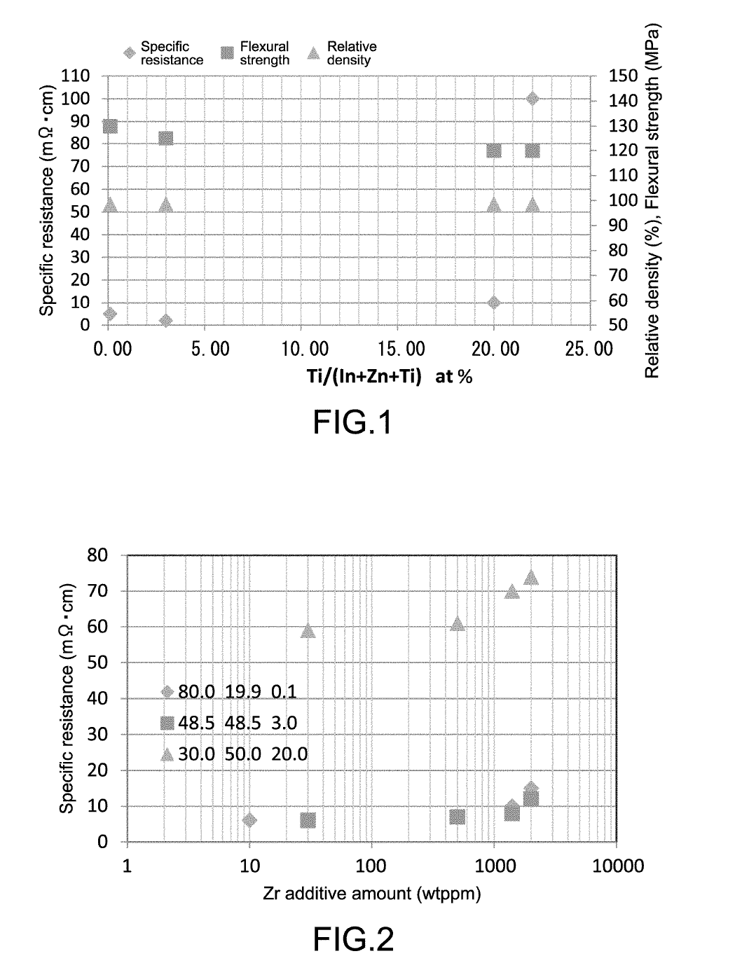

For example, FIG. 1 shows the relationship between the Ti atomic ratio and the specific resistance, and the flexural strength and the relative density in the In—Zn—Ti—O sintered body. In FIG. 1, the horizontal, the vertical axis on the left, and the vertical axis on the right respectively show the Ti atomic ratio, the specific resistance (mΩ·cm) (⋄ plot), and the flexural strength (MPa) (□ plot) and the relative density (%) (Δ plot).

As shown in FIG. 1, by setting the Ti atomic ratio to not less than 0.1% and not more than 20%, it is possible to achieve the specific resistance of not more than 10 mΩ·cm, the flexural strength (bending strength) of not less than approximately 125 MPa, and the relative density of not less than 95%. Further, in the sample having the Ti atomic ratio of 22%, control is difficult because the value of the specific resistance is rapidly increased. From such a viewpoint, the Ti atomic ratio is preferably not more than 20%.

Meanwhile, in the above-mentioned sintered body (sputtering target), a weight ratio of Zr (zirconium) (hereinafter, referred to also as Zr weight ratio) with respect to a sum of an indium oxide, a zinc oxide, a titanium oxide, and a zirconium oxide is not less than 10 ppm and not more than 2,000 ppm. That is, the amount of metal Zr detected from the metal oxide constituting the above-mentioned sintered body is not less than 10 ppm and not more than 2,000 ppm in weight ratio.

In the case where the Zr weight ratio is less than 10 ppm, the effect of suppressing the grain growth of the titanium oxide is small. In the case where the Zr weight ratio exceeds 2,000 ppm, the zirconium oxide (ZrO₂) is precipitated alone. As a result, the specific resistance is increased, and abnormal discharge easily occurs in the case of being used for DC sputtering.

The zirconium oxide suppresses the grain growth of the titanium oxide (TiO₂), and largely contributes to the increase in the flexural strength mainly. Specifically, the zirconium oxide (ZrO₂) is precipitated at grain boundaries of oxide crystals, and fulfills the function of preventing the crystal growth (pinning effect). Accordingly, it is possible to obtain a sputtering target in which crystalline grains are dense, so that the mechanical strength (flexural strength) is improved, and occurrence of nodules and abnormal discharge is further suppressed.

FIG. 2 to FIG. 4 respectively show the relationship between the Zr weight ratio and the specific resistance, the flexural strength, and the relative density in the In—Zn—Ti—O sintered body. In these figures, the horizontal axis represents the Zr weight ratio (additive amount of Zr, wtppm), and the vertical axis represents the specific resistance (mΩ·cm), the flexural strength (MPa), and the relative density (%), respectively. In each figure, plots of “⋄”, “□”, and “Δ” represent sintered bodies of three systems having different Ti atomic ratios, and respectively correspond to sintered bodies in which the ratio of In:Zn:Ti is 80:19.9:0.1, 48.5:48.5:3, and 30:50:20.

As shown in FIG. 2 to FIG. 4, in the case where the Zr weight ratio is not less than 10 ppm and not more than 2,000 ppm, for all the systems, the specific resistance of not more than 80 mΩ·cm, the flexural strength of not less than 100 MPa, and the relative density of not less than 97% can be achieved.

As shown in FIG. 2, in the case where the Zr weight ratio is not less than 1,000 ppm, for all the systems, the specific resistance tends to start to be increased. Further, as compared with the sintered body having the Ti atomic ratio of 20%, the sintered bodies having the Ti atomic ratios of 0.1% and 3% each have an extremely low specific resistance, which is suppressed to be not more than approximately 20 mΩ·cm. Therefore, it is possible to achieve stable discharge in not only DC sputtering but also sputtering methods such as AC sputtering and RF sputtering, and the like.

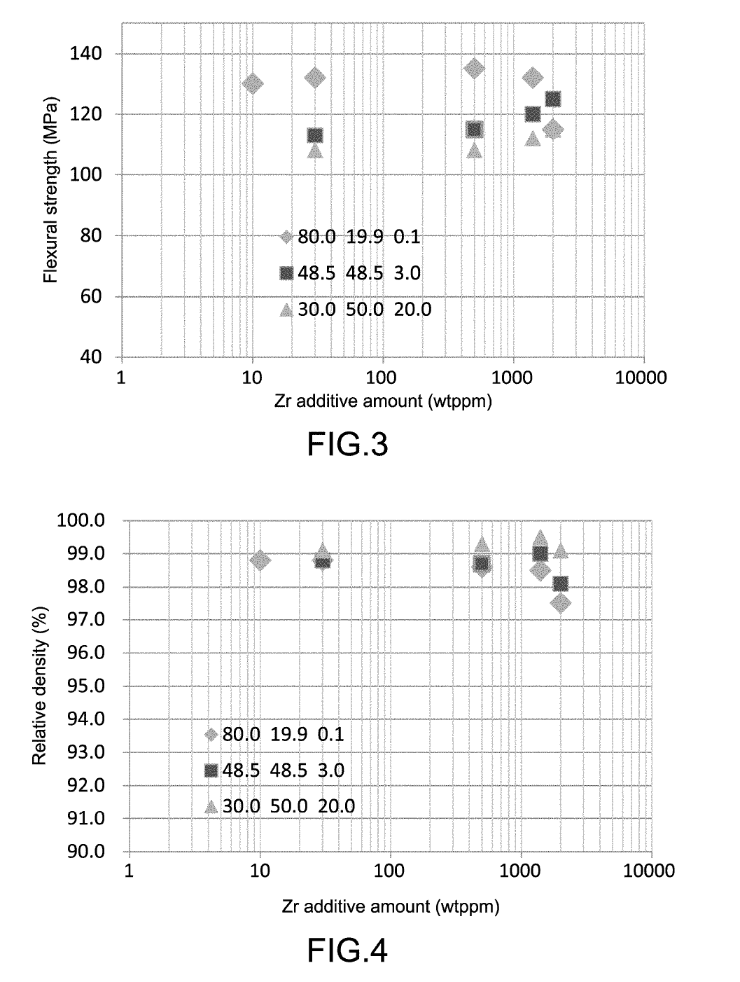

Further, as shown in FIG. 3, in the case where the Zr weight ratio exceeds 2,000 ppm, although the flexural strength tends to be increased for the sintered bodies having the Ti atomic ratios of 3% and 20%, the flexural strength tends to be reduced for the sintered body having the Ti atomic ratio of 0.1%.

Further, as shown in FIG. 4, in the case where the Zr weight ratio exceeds 2,000 ppm, the relative density tends to start to be reduced for all the systems. In particular, in the sintered bodies having the Ti atomic ratios of 0.1% and 3%, the reduction rate of the relative density is relatively large.

As is apparent from the above description, the Zr weight ratio in the In—Zn—Ti—O sintered body has a close correlation with the specific resistance, the flexural strength, and the relative density of the sintered body. In particular, when paying attention to the sintered body having the Ti atomic ratio of 0.1%, it has a strong correlation with the Zr weight ratio, and the change in specific resistance, flexural strength, and relative density with the increase in Zr weight ratio is large, as compared with the sintered bodies of other systems. Among such tendencies, particularly, the change in flexural strength is large because the atomic ratios of Ti and Zr in the sintered body are balanced with the increase in Zr weight ratio, Zr is excessively added to Ti, and thus, the amount of zirconium oxide precipitated at grain boundaries of oxide crystals becomes excessive, which easily causes breaks originating from this more and reduces the mechanical strength of the sintered body.

In this regard, by limiting the Zr weight ratio so that the atomic ratio of Zr is equal to or less than the atomic ratio of the Ti atomic ratio in the sintered body, preferably not more than 0.6 of the Ti atomic ratio, and setting the Zr weight ratio to not more than 1,400 ppm, it is possible to simultaneously suppress the increase in specific resistance and the reduction in flexural strength and relative density. Note that the lower limit of the Zr weight ratio can be not less than 10 ppm, preferably, not less than 30 ppm.

The oxide constituting the above-mentioned sintered body typically has the average crystalline grain size of not more than 15 μm and the specific resistance of not less than 0.1 mΩ·cm and not more than 300 mΩ·cm.

Since the crystal grain growth is suppressed by the addition of Zr, the average crystalline grain size of the oxide sintered body is suppressed to be not more than 15 μm, which makes it possible to achieve the improvement of the flexural strength while suppressing the increase in specific resistance. Further, since the specific resistance is suppressed to be not more than 300 mΩ·cm, DC sputtering of the sputtering target formed of the oxide sintered body becomes possible. In order to ensure more stable sputtering discharge, the specific resistance of the oxide sintered body is preferably not more than 80 mΩ·cm.

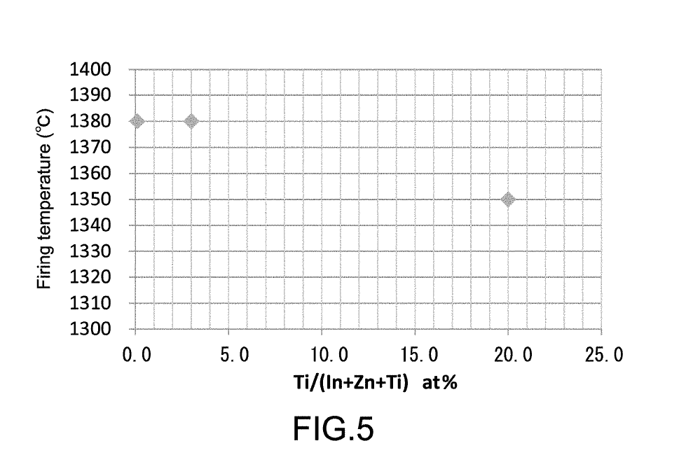

Further, by adding a titanium oxide (TiO₂) as a sintering aid, it is possible to reduce the firing temperature. For example, FIG. 5 is an experimental result showing a Ti atomic ratio dependency of the firing temperature of the In—Zn—Ti—O sintered body having a relative density of 98.6% to 98.7%. As shown in FIG. 5, the firing temperature tends to decrease as the Ti atomic ratio is larger. Accordingly, it is possible to suppress the crystal grain growth due to the increase in firing temperature. Further, since the firing temperature can be reduced, there is an advantage that stress hardly remains inside the target during cooling after firing in the target production step.

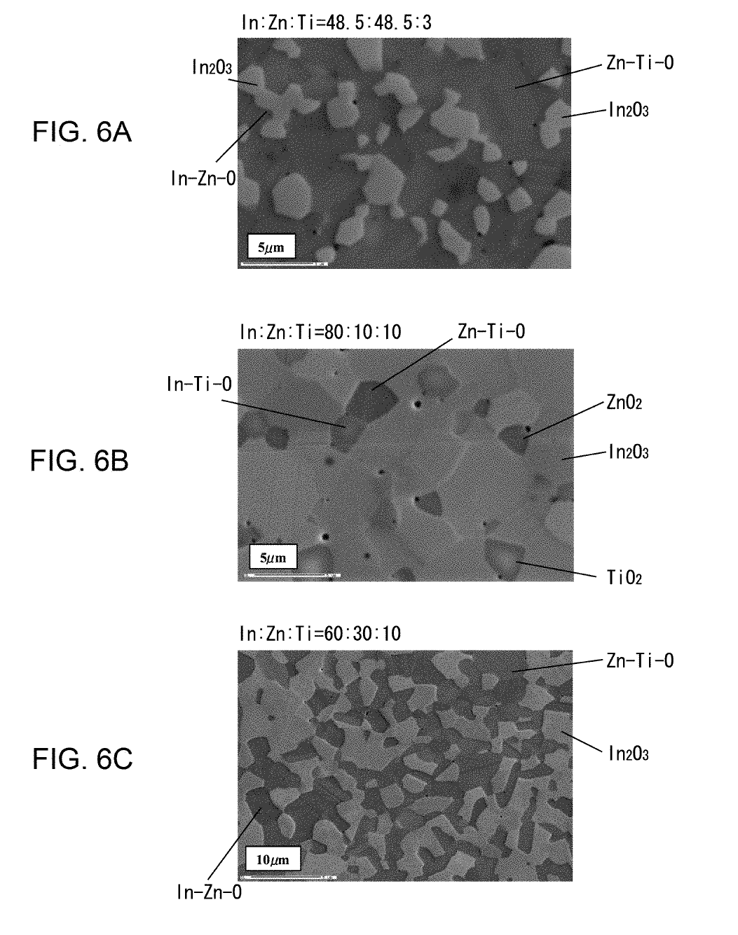

Next, Part A to Part C of FIG. 6 are each an SEM image showing crystalline structures of In—Zn—Ti—O sintered bodies of three systems having different composition ratios. Part A, Part B, and Part C respectively show the sintered body having the composition ratio of In:Zn:Ti=48.5:48.5:3, the sintered body having the composition ratio of In:Zn:Ti=80:10:10, and the sintered body having the composition ratio of In:Zn:Ti=60:30:10.

It is conceivable that in the SEM images shown in Part A to Part C of FIG. 6, the white portion is a phase mainly formed of an In₂O₃ phase, and the surrounding portion is a single layer of an In—Zn—O phase, an In—Ti—O phase, a Zn—Ti—O phase, or a ZnO₂ phase, or an alloy phase or compound phase of two or more of these phases. The average particle size of crystals constituting these phases was not more than 15 μm.

Note that the quadrature method (JIS H0501) was used for measuring the average particle size of the crystals constituting the phases. This method is a method of calculating the average particle size of crystalline grains using an electron microscope. Specifically, a photograph of crystalline grains is taken with an electron microscope, and a rectangle of approximately 5,000 mm² is drawn on the photograph. The sum of the number of crystalline grains completely contained within this area and half of the number of crystalline grains cut around the rectangle is regarded as the total number of crystalline grains, and the average crystalline grain size is calculated by the following formula.

d=(1/M)√(A/n) (1)

n=z+(w/2) (2)

Note that d represents the average crystalline grain size, M represents the used magnification, A represents the measured area, z represents the number of crystalline grains completely contained in Part A, w represents the number of crystalline grains in the peripheral portion, and n represents the total number of crystal grains.

Meanwhile, black dots observed in the SEM images of Part A to Part C of FIG. 6 are presumed to be pinholes contained in the sintered body. When the size of each of the pinholes was measured, each pinhole has the circle equivalent diameter of not more than 1 μm.

According to the sputtering target formed of the In—Zn—Ti—O sintered body of this embodiment configured as described above, since the Ti atomic ratio is not less than 0.1% and not more than 20%, and the Zr weight ratio is not less than 10 ppm and not more than 2,000 ppm, it is possible to obtain a sputtering target having a high density (not less than 95%), a low specific resistance (not more than 300 mΩ·cm), and a high flexural strength. Accordingly, ensuring stable DC sputtering and occurrence of breaks and cracks can be suppressed, so that it is possible to suppress occurrence of abnormal discharge and nodules during sputtering discharge and improve the handling property of the sputtering target.

### Method of Producing Sputtering Target

Next, a typical method of producing the sputtering target according to this embodiment will be described.

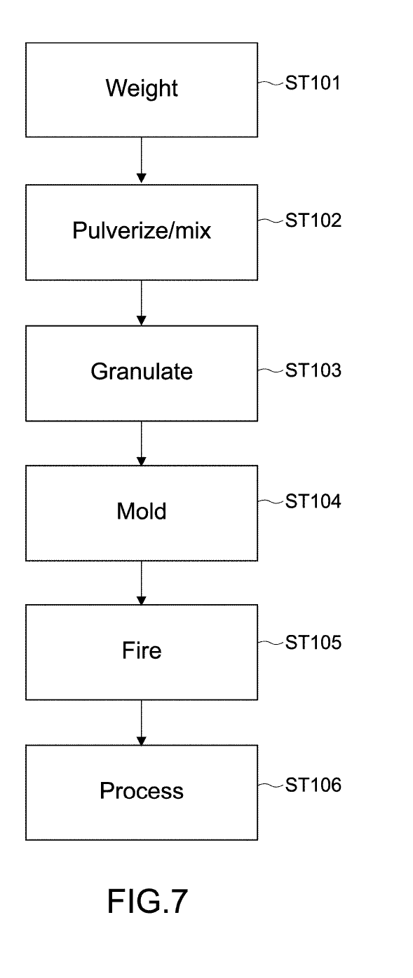

FIG. 7 shows a process flow describing a method of producing an oxide-sintered-body sputtering target according to an embodiment of the present invention. The production method according to this embodiment includes a weighting step (Step 101), a pulverization/mixing step (Step 102), a granulation step (Step 103), a molding step (step 104), a firing step (Step 105), and a processing step (Step 106).

(Weighting and Pulverization/Mixing Steps)

As raw material powders, an indium oxide powder, a zinc oxide powder, a titanium oxide powder, and a zirconium oxide powder are prepared. The average particle size of the powder (including the compound powder) used as the raw material of the oxide sintered body is preferably not more than 5 μm.

As the titanium oxide powder, a titanium oxide powder having a relatively high rutile ratio is used. In the case where TiO₂ raw materials having similar average particle sizes of raw materials and different rutile ratios are used, since one having a higher rutile ratio contracts more from the results of TMA (thermomechanical analysis) showing the amount of contraction, the relative density of the sintered body to be obtained is higher than that in the case where the rutile ratio is low, as will be described later. In this embodiment, as the titanium oxide powder, a raw material powder of a titanium oxide having the rutile ratio of not less than 80% and the average crystalline grain size of not more than 3 μm is used.

Next, these powders are mixes to produce mixed powder in which an atomic ratio of titanium (Ti atomic ratio) with respect to a sum of indium, zinc, and titanium is not less than 0.1% and not more than 20% and a weight ratio of zirconium (Zr weight ratio) with respect to a sum of an indium oxide, an zinc oxide, an titanium oxide, and an zirconium oxide is not less than 10 ppm and not more than 2,000 ppm.

In order to mix the raw material powders, a wet mixing method using a ball mill apparatus can be adopted. Other than this, a bead mill apparatus, a starburst apparatus, a V-type mixer, a tumbler mixer and the like can be applied, and a favorable oxide sintered body can be obtained also by these.

When mixing the raw material powders, it is preferable to perform the mixing by a wet mixing method using an apparatus capable of simultaneously performing dispersion and pulverization (crushing) of raw material powders. The raw material powders may be mixed by a dry method using a V-type mixer, a tumbler mixer, or the like, and then, a slurry may be produced and pulverized (crushed) using a bead mill method, a starburst method, or the like.

The raw material powders produced by a dry mixing method tend to be aggregated or biased as compared with those produced by a wet mixing method. In the case where the raw material powders are aggregated or biased, there is a possibility that a difference in sintering speed occurs at the time of sintering the raw material powders and a desired sintered body cannot be obtained. In a dry mixing method, the possibility of problems with the density, resistance value, crystalline structure, crystalline grain, and the like of the sintered body due to the aggregation or biasing of the raw material powders is higher than that in a wet mixing method.

In this embodiment, although mixing and pulverization (crushing) of the raw material powders are simultaneously performed by a wet mixing method, a ceramics medium may be used for pulverizing (crushing) the raw material powders. A medium formed of ZrO₂ is most preferable. By using the medium formed of ZrO₂, mixing and pulverization (crushing) of the raw material powders in a short time becomes possible. Further, by adding ZrO₂ to the raw material powders, an effect of improving the strength of the sintered body can be achieved. The amount of Zr added to the row material powders using the medium formed of ZrO₂ is approximately 10 to 10,000 ppm in a weight ratio, and the wet mixing time at that time is in the range of 5 to 100 hr, preferably, in the range of 5 to 80 hr.

Note that in pulverization (crushing) of the raw material powders using the medium formed of ZrO₂, the mixing amount of the zirconium oxide powder may be adjusted considering the amount of ZrO₂ to be mixed in the raw material powders, or the Zr weight ratio of the sintered body may be adjusted with ZrO₂ to be mixed from the above-mentioned medium without using the zirconium oxide powder. In this sense, “preparing a zirconium oxide powder” includes not only preparing a zirconium oxide powder but also pulverizing (crushing) raw material powders using a medium formed of ZrO₂.

(Granulation Step)

Next, 0.1 to 5.0 wt % of binder is added to the raw materials mixed and pulverized (crushed) by a wet mixing method, followed by solid-liquid separation, drying, and granulation. The additive amount of the binder is preferably in the range of 0.5 to 3.0 wt %. Further, the solid-liquid separation, drying, and granulation of the raw material powders after the wet mixing is not particularly limited, and a well-known production method such as spray drying with a spray dryer can be adopted.

(Molding Step)

Next, the obtained granulated powder is filled in a mold formed of rubber or metal, and molding is performed under a pressure of not less than 1.0 ton/cm² by a cold isostatic pressing apparatus (CIP). Other than this, it is also possible to obtain an oxide sintered body by applying pressure with hot pressure such as hot pressing as a well-known production method. However, considering the cost of the production and increase in size of the oxide sintered body, cold press molding is better.

By defatting the binder contained in the obtained molded body before sintering, the amount of impurities in the oxide sintered body is small and factors obstructing the sintering reaction of the raw material powders at the time of sintering are reduced, as compared with an oxide sintered body on which no defatting is performed. Therefore, a better oxide sintered body can be obtained. The defatting of the molded body is preferably performed in an air atmosphere or an oxygen atmosphere (atmosphere having a higher oxygen concentration than the atmosphere). It is preferable that the atmosphere in the furnace at that time is always in a fresh state. The defatting temperature is appropriately set in the range of 450° C. to 800° C. depending on the type of the added binder.

(Firing Step)

The sintering of the molded body is performed in either an air atmosphere or an oxygen atmosphere (atmosphere having a higher oxygen concentration than the atmosphere), and the sintering temperature is in the range of 800 to 1600° C. In the case of the sintering temperature of not more than 800° C., the sintering does not proceed, and the density becomes poor. In the case of the sintering temperature of not less than 1600° C., the raw material powders may evaporate.

The sintering temperature is preferably not less than 1240° C. and not more than 1,400° C. The rate of temperature increase from room temperature at this time is preferably 0.1° C./min to 5.0° C./min. Accordingly, an oxide sintered body having a high density and uniform crystalline structure with a relative density of not less than 95% can be obtained.

The holding time of the sintering temperature may be appropriately set depending on the shape and weight of the molded body within a range of 2 hr to 20 hr. In the case where the holding time is shorter than the time required for the weight of the molded body, the density of the oxide sintered body becomes poor. In the case where the holding time is longer, it becomes a factor of coarsening of crystalline grains, coarsening of pores, reduction in strength of the sintered body, and the like.

In this embodiment, since a raw material powder of a titanium oxide having the rutile ratio of not less than 80% is used as the titanium oxide powder, the relative density is higher than that in the case where a raw material powder of a titanium oxide having the rutile ratio of less than 80% is used, and it is possible to increase the rate of temperature increase.

For example, in the case where a material having a low rutile ratio is selected as the titanium oxide powder, it is necessary to slowly perform heating at a temperature (600 to 1,000° C.) at which anatase undergoes phase transition to rutile. This is because when the rate of temperature increase is set high (e.g., not less than 1° C./min), the surface layer of the sintered body is converted into rutile beforehand by phase transition from anatase to rutile in the sintering process to form a shell, thereby preventing the inside of the sintered body from contracting when being sintered later, which makes it difficult for the density to increase. Further, cracks likely to occur in the surface layer of the sintered body, and pinholes are likely to occur inside the sintered body. That is, in the case of selecting a material having a low rutile ratio, it takes time to sinter and the relative density is reduced. Meanwhile, selecting a material having a high rutile ratio has an advantage that the above-mentioned problem does not occur even at the rate of temperature increase of approximately 5° C./min in the temperature range of the phase transition of 600 to 1,000° C.

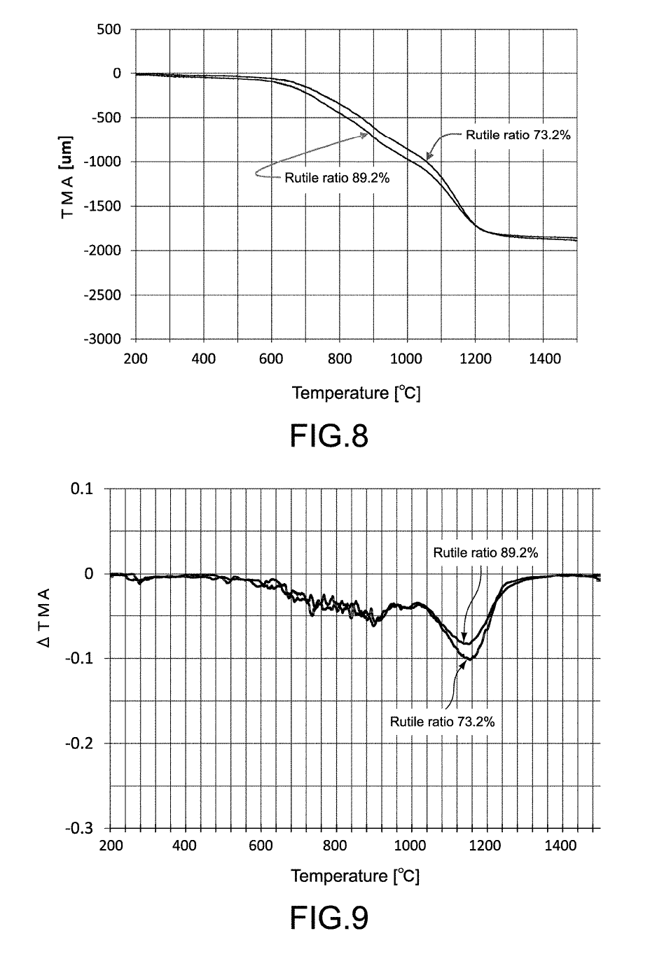

FIG. 8 is an experimental result showing an evaluation result of TMA (Thermomechanical Analysis) of a powder sample obtained by adding a titanium oxide powder having rutile ratios of not less than 80% (89.2%) and a titanium oxide powder having rutile ratios of less than 80% (73.2%) to raw material powders containing an indium oxide powder, a zinc oxide powder, and a zirconium oxide powder. Further, FIG. 9 shows the time differential value (ΔTMA) of the experimental result obtained in FIG. 8. In the experiment, the dimensional changes in the height direction of the sample were measured when the sample obtained by compacting powder into a rod shape was heated while applying a static constant load to the sample.

As shown in FIG. 8, when sintering proceeds, it contracts, and the value of TMA becomes minus. Further, when the sintering is completed, the value of TMA becomes constant. At this time, it can be seen that the contraction due to heating proceeds faster as the sample having a higher rutile ratio. Therefore, the density of the sample tends to be higher than that of the sample having a low rutile ratio.

Further, as shown in FIG. 9, regardless of the degree of the rutile ratio, in any of the samples, ΔTMA, i.e., the dimensional changes in the height direction of the sample are in the vicinity of zero from around 1240° C. From this fact, it is expected that sintering is completed at around 1240° C. From the above, it can be seen that a sintered body having a high density can be obtained at a firing temperature of not less than 1240° C.

Further, in this embodiment, a raw material powder of a titanium oxide having the average crystalline grain size of not more than 3 μm is used as the titanium oxide powder. Since the raw material powder having a small average crystalline grain size has a relatively large specific surface area, the energy of the surface thereof is high and it is easily sintered. That is, since the sinterability is enhanced, it becomes possible to prepare a sintered body having a high density in a relatively short time.

(Processing Step)

The sintered body prepared as described above is machined into a plate shape having a desired shape, size, and thickness, thereby preparing a sputtering target formed of the In—Zn—Ti—O sintered body. The sputtering target is integrated with a backing plate (not shown) by brazing.

### Experimental Example

Next, experimental examples conducted by the present inventors will be described. In the following experimental examples, a plurality of In—Zn—Ti—O sintered bodies having different Ti atomic ratios and Zr weight ratios were prepared, and the specific resistance, the flexural strength, and the relative density thereof were measured. As the specific resistance, a value measured using a well-known four-terminal method was used. As the flexural strength, a value measured by a three-point flexural test according to JIS R1601 was used. The relative density was obtained by calculating the ratio between the apparent density of the sintered body and the theoretical density.

(Sample 1)

An In—Zn—Ti—O sintered body having a ratio of In:Zn:Ti of 80.0:19.9:0.1 and a Zr weight ratio of 10 ppm was prepared in a shape of 170 mm in length, 170 mm in width, and 11 mm in thickness under firing conditions of 1380° C. and eight hours. The specific resistance, flexural strength, and relative density of the obtained sintered body were measured and found to be 6 mΩ·cm, 130 MPa, and 98.8%, respectively.

Note that regarding the measurement of the flexural strength, a sample cut into size of 40 mm in length, 4 mm in width, and 3 mm in thickness from the sintered body prepared with the above-mentioned dimension was used.

(Sample 2)

A sintered body was prepared under conditions similar to those for the sample 1 except that the Zr weight ratio was 30 ppm. The specific resistance, flexural strength, and relative density of the obtained sintered body were measured and found to be 6 mΩ·cm, 132 MPa, and 98.8%, respectively.

(Sample 3)

A sintered body was prepared under conditions similar to those for the sample 1 except that the Zr weight ratio was 500 ppm. The specific resistance, flexural strength, and relative density of the obtained sintered body were measured and found to be 7 mΩ·cm, 135 MPa, and 98.6%, respectively.

(Sample 4)

A sintered body was prepared under conditions similar to those for the sample 1 except that the Zr weight ratio was 1,400 ppm. The specific resistance, flexural strength, and relative density of the obtained sintered body were measured and found to be 10 mΩ·cm, 132 MPa, and 98.5%, respectively.

(Sample 5)

A sintered body was prepared under conditions similar to those for the sample 1 except that the Zr weight ratio was 2,000 ppm. The specific resistance, flexural strength, and relative density of the obtained sintered body were measured and found to be 15 mΩ·cm, 115 MPa, and 97.5%, respectively.

(Sample 6)

A sintered body was prepared under conditions similar to those for the sample 1 except that the ratio of In:Zn:Ti was 48.5:48.5:3.0 and the Zr weight ratio was 30 ppm. The specific resistance, flexural strength, and relative density of the obtained sintered body were measured and found to be 6 mΩ·cm, 113 MPa, and 98.8%, respectively.

(Sample 7)

A sintered body was prepared under conditions similar to those for the sample 6 except that the Zr weight ratio was 500 ppm. The specific resistance, flexural strength, and relative density of the obtained sintered body were measured and found to be 7 mΩ·cm, 115 MPa, and 98.7%, respectively.

(Sample 8)

A sintered body was prepared under conditions similar to those for the sample 6 except that the Zr weight ratio was 1,400 ppm. The specific resistance, flexural strength, and relative density of the obtained sintered body were measured and found to be 8 mΩ·cm, 120 MPa, and 90.0%, respectively.

(Sample 9)

A sintered body was prepared under conditions similar to those for the sample 6 except that the Zr weight ratio was 2,000 ppm. The specific resistance, flexural strength, and relative density of the obtained sintered body were measured and found to be 12 mΩ·cm, 125 MPa, and 98.1%, respectively.

(Sample 10)

A sintered body was prepared under conditions similar to those for the sample 1 except that the ratio of In:Zn:Ti was 30.0:50.0:20.0 and the Zr weight ratio was 30 ppm. The specific resistance, flexural strength, and relative density of the obtained sintered body were measured and found to be 59 mΩ·cm, 108 MPa, and 99.1%, respectively.

(Sample 11)

A sintered body was prepared under conditions similar to those for the sample 10 except that the Zr weight ratio was 500 ppm. The specific resistance, flexural strength, and relative density of the obtained sintered body were measured and found to be 61 mΩ·cm, 108 MPa, and 99.3%, respectively.

(Sample 12)

A sintered body was prepared under conditions similar to those for the sample 6 except that the Zr weight ratio was 1,400 ppm. The specific resistance, flexural strength, and relative density of the obtained sintered body were measured and found to be 70 mΩ·cm, 112 MPa, and 99.5%, respectively.

(Sample 13)

A sintered body was prepared under conditions similar to those for the sample 6 except that the Zr weight ratio was 2,000 ppm. The specific resistance, flexural strength, and relative density of the obtained sintered body were measured and found to be 74 mΩ·cm, 115 MPa, and 99.1%, respectively.

(Sample 14)

A sintered body was prepared under conditions similar to those for the sample 1 except that the ratio of In:Zn:Ti was 70.0:29.9:0.1, the Zr weight ratio was 500 ppm, and the sintering time was 4 hours. The specific resistance, flexural strength, and relative density of the obtained sintered body were measured and found to be 5 mΩ·cm, 130 MPa, and 98.6%, respectively.

(Sample 15)

A sintered body was prepared under conditions similar to those for the sample 1 except that the ratio of In:Zn:Ti was 70.0:27.0:3.0, the Zr weight ratio was 500 ppm, and the sintering time was 4 hours. The specific resistance, flexural strength, and relative density of the obtained sintered body were measured and found to be 2 mΩ·cm, 125 MPa, and 98.7%, respectively.

(Sample 16)

A sintered body was prepared under conditions similar to those for the sample 1 except that the ratio of In:Zn:Ti was 70.0:10.0:20.0, the Zr weight ratio was 500 ppm, the firing temperature was 1,350° C., and the sintering time was 4 hours. The specific resistance, flexural strength, and relative density of the obtained sintered body were measured and found to be 10 mΩ·cm, 120 MPa, and 98.7%, respectively.

(Sample 17)

A sintered body was prepared under conditions similar to those for the sample 1 except that the ratio of In:Zn:Ti was 70.0:8.0:22.0, the Zr weight ratio was 500 ppm, the firing temperature was 1,330° C., and the sintering time was 4 hours. The specific resistance, flexural strength, and relative density of the obtained sintered body were measured and found to be 100 mΩ·cm, 120 MPa, and 98.7%, respectively.

The compositions, evaluation results, and firing conditions of the samples 1 to 19 are summarized in Table 1.

TABLE 1

| | | | | | 4 terminal | JIS R1601 | | | |
|---|---|---|---|---|---|---|---|---|---|
| | | | | | method | 3 point | | | |
| | Composition | | | Zr additive | Specific | flexural | Relative | Firing | Firing |
| Sample | (at %) | | | amount | resistance | strength | density | temperature | time |
| No. | In | Zn | Ti | wtppm | mΩ · cm | MPa | % | ° C. | hr |
| 1 | 80.0 | 19.9 | 0.1 | 10 | 6 | 130 | 98.8 | 1380 | 8 |
| 2 | 80.0 | 19.9 | 0.1 | 30 | 6 | 132 | 98.8 | 1380 | 8 |
| 3 | 80.0 | 19.9 | 0.1 | 500 | 7 | 135 | 98.6 | 1380 | 8 |
| 4 | 80.0 | 19.9 | 0.1 | 1400 | 10 | 132 | 98.5 | 1380 | 8 |
| 5 | 80.0 | 19.9 | 0.1 | 2000 | 15 | 115 | 97.5 | 1380 | 8 |
| 6 | 48.5 | 48.5 | 3.0 | 30 | 6 | 113 | 98.8 | 1380 | 8 |
| 7 | 48.5 | 48.5 | 3.0 | 500 | 7 | 115 | 98.7 | 1380 | 8 |
| 8 | 48.5 | 48.5 | 3.0 | 1400 | 8 | 120 | 99.0 | 1380 | 8 |
| 9 | 48.5 | 48.5 | 3.0 | 2000 | 12 | 125 | 98.1 | 1380 | 8 |
| 10 | 30.0 | 50.0 | 20.0 | 30 | 59 | 108 | 99.1 | 1380 | 8 |
| 11 | 30.0 | 50.0 | 20.0 | 500 | 61 | 108 | 99.3 | 1380 | 8 |
| 12 | 30.0 | 50.0 | 20.0 | 1400 | 70 | 112 | 99.5 | 1380 | 8 |
| 13 | 30.0 | 50.0 | 20.0 | 2000 | 74 | 115 | 99.1 | 1380 | 8 |
| 14 | 70.0 | 29.9 | 0.1 | 500 | 5 | 130 | 98.6 | 1380 | 4 |
| 15 | 70.0 | 27.0 | 3.0 | 500 | 2 | 125 | 98.7 | 1380 | 4 |
| 16 | 70.0 | 10.0 | 20.0 | 500 | 10 | 120 | 98.7 | 1350 | 4 |
| 17 | 70.0 | 8.0 | 22.0 | 500 | 100 | 120 | 98.7 | 1330 | 4 |

As shown in Table 1, in the samples 1 to 16 having the Ti atomic ratio of not less than 0.1% and not more than 20% and the Zr weight ratio of not less than 10 ppm and not more than 2,000 ppm, a specific resistance of not more than 74 mΩ·cm, a flexural strength of not less than 108 MPa, and a relative density of not less than 97.5% can be achieved.

Note that the sample 17 having the Ti atomic ratio of 22% has a relatively high specific resistance of 100 mΩ·cm. Further, it was confirmed that as the Ti atomic ratio was increased, the flexural strength tended to be reduced (see FIG. 1).

Regarding the specific resistance, values of not more than 15 mΩ·cm are achieved for the samples 1 to 9 and the samples 14 to 16. These values show substantially the same results as the specific resistance value (approximately 20 mΩ·cm) of IGZO that is a representative metal oxide, and it is possible to maintain stable discharge when performing DC sputtering.

In comparison, although the samples 10 to 13 and the sample 17 each have the specific resistance of more than 50 mΩ·cm, the value is within the range capable of suppressing occurrence of abnormal discharge and nodules by controlling various conditions (atmospheric temperature, type of gas to be introduced, and the like) at the time of DC sputtering.

Note that the sample 17 shows the result of a relatively large specific resistance of 100 mΩ·cm because of the Ti atomic ratio of 22%. The Zr weight ratio of the sample 17 is 500 ppm, and it is expected that when the Zr weight ratio is increased to 2,000 ppm in the Ti atomic ratio of the sample 17, the specific resistance value exceeds 300 mΩ·cm, considering the tendency that the specific resistance value is increased as the Zr weight ratio is increased, which is observed in the samples 1 to 16. In this case, discharge itself by DC sputtering becomes difficult. In this regard, in the case where the Ti atomic ratio is large, it is also possible to prevent the specific resistance value from being significantly increased by limiting the Zr weight ratio. That is, even in the case where the Ti atomic ratio exceeds 20% as in the sample 17, it is possible to suppress the specific resistance value of the sintered body to be obtained to approximately 100 mΩ·cm by limiting the Zr weight ratio to not more than 500 ppm.

Further, when the Ti atomic ratio was set to be constant, it was confirmed that the specific resistance was increased as the Zr weight ratio was increased (see FIG. 2). When the Zr weight ratio was not less than 1,400 ppm, it was confirmed that the flexural strength was reduced in the sample having the Ti atomic ratio of 0.1% and was increased in the sample having the Ti atomic ratio of not less than 3% (see FIG. 3). Meanwhile, it was confirmed that the relative density was tended to be reduced in any of the samples having the Zr weight ratio of not less than 1,400 ppm (see FIG. 4).

Further, as shown in the samples 14 to 16, in obtaining a sintered body having a relative density of 98.6% to 98.7%, it was confirmed that the firing temperature tended to be reduced as the Ti atomic ratio became larger (see FIG. 5).

1. An oxide-sintered-body sputtering target formed of a sintered body containing an indium oxide, a zinc oxide, a titanium oxide, and a zirconium oxide, an atomic ratio of titanium with respect to a sum of indium, zinc, and titanium being not less than 0.1% and not more than 20%, a weight ratio of zirconium with respect to a sum of the indium oxide, the zinc oxide, the titanium oxide, and the zirconium oxide being not less than 10 ppm and not more than 2,000 ppm.

2. The oxide-sintered-body sputtering target according to claim 1, wherein
the weight ratio of zirconium with respect to the sum of the indium oxide, the zinc oxide, the titanium oxide, and the zirconium oxide is not less than 30 ppm and not more than 1,400 ppm, and
an atomic ratio of zirconium with respect to titanium is not more than 0.6.

3. The oxide-sintered-body sputtering target according to claim 1, wherein
the sintered body has a relative density of not less than 95%.

4. The oxide-sintered-body sputtering target according to claim 1, wherein
each of the oxides constituting the sintered body has an average crystalline grain size of not more than 15 μm and a specific resistance of not less than 0.1 mΩ·cm and not more than 300 mΩ·cm.

5. The oxide-sintered-body sputtering target according to claim 1, wherein
the sintered body includes an alloy phase or a compound phase of an In₂O₃ phase and at least one of an In—Ti—O phase, a Zn—Ti—O phase, and an In—Zn—O phase.

6. The oxide-sintered-body sputtering target according to claim 1, wherein
the sintered body includes an In₂O₃ phase having an average particle size of not more than 15 μm.

7. The oxide-sintered-body sputtering target according to claim 1, wherein
a pinhole in the sintered body has a circle equivalent diameter of not more than 1 μm.

8. A method of producing an oxide-sintered-body sputtering target, comprising:
preparing an indium oxide powder, a zinc oxide powder, a titanium oxide powder, and a zirconium oxide powder;
mixing the powders to prepare mixed powder in which an atomic ratio of titanium with respect to a sum of indium, zinc, and titanium is not less than 0.1% and not more than 20% and a weight ratio of zirconium with respect to a sum of an indium oxide, an zinc oxide, an titanium oxide, and an zirconium oxide is not less than 10 ppm and not more than 2,000 ppm; and
firing the mixed powder at a predetermined temperature.

9. The method of producing an oxide-sintered-body sputtering target according to claim 8, wherein
as the titanium oxide powder, a raw material powder of a titanium oxide having a rutile ratio of not less than 80% and an average crystalline grain size of not more than 3 μm is used.

10. The method of producing an oxide-sintered-body sputtering target according to claim 8, wherein
the predetermined temperature is not less than 1,240° C. and not more than 1,400° C.
